(19) United States
(12) Patent Application Publication
(10) Pub. No.: US 2014/0010997 A1
(43) Pub. Date: Jan. 9, 2014

(54) METHOD FOR CONTROLLING THE STRUCTURE OF PYROLYTIC CARBON

(71) Applicants: Jim PATEL, Parkdale (AU); James GUNNING, East Brunswick (AU)

(72) Inventors: Jim PATEL, Parkdale (AU); James GUNNING, East Brunswick (AU)

(73) Assignee: Commonwealth Scientific and Industrial Research Organisation, Campbell (AU)

(21) Appl. No.: 13/904,610

(22) Filed: May 29, 2013

(30) Foreign Application Priority Data
Jun. 27, 2012 (AU) 2012902732

(51) Int. Cl. C23C 16/26

(52) U.S. Cl. CPC C23C 16/26
USPC 428/172; 427/249.2; 428/156

(57) ABSTRACT

A process for the production of pyrolytic carbon comprising the steps of: (A) depositing pyrolytic carbon on a substrate, and (B) controlling the structure of the deposited pyrolytic carbon through use of a Volmer-Weber island growth model.

### TECHNICAL FIELD

The invention relates to the control of pyrolytic carbon structures and in particular the control of anisotropic pyrolytic material structure according to the Volmer-Weber island growth mechanism.

### BACKGROUND

The nature of pyrolytic carbon growth has been debated for over half a century, and yet there is no consensus regarding the mechanism. The physical properties of pyrolytic carbon-based materials are well known to be dependent on the carbon structure, which is itself determined by the growth conditions².

Pyrolytic carbon constitutes an important class of carbon material and is employed in a wide range of industrial and consumer applications. Because blood clots do not easily form on it, it is often advisable to line a blood-contacting prosthesis with this material in order to reduce the risk of thrombosis. For example, it finds use in artificial hearts and artificial heart valves. Blood vessel stents, by contrast, are often lined with a polymer that has heparin as a pendant group, relying on drug action to prevent clotting. This is at least partly because of pyrolytic carbon's brittleness and the large amount of permanent deformation which a stent undergoes during expansion.

Pyrolytic carbon is also in medical use to coat anatomically correct orthopaedic implants, a.k.a. replacement joints. In this application it is currently marketed under the name “PyroCarbon”. These implants have been approved by the U.S. Food and Drug Administration for use in the hand for metacarpophalangeal (knuckle) replacements. They are produced by two companies: Tornier (BioProfile) and Ascension Orthopedics. The FDA has also approved PyroCarbon interphalangeal joint replacements under the Humanitarian Device Exemption.

Other uses include:
nonreinforced for missile nose cones, and ablative (boiloff-cooled) rocket motors.
In fiber form, it is used to reinforce plastics and metals (see Carbon fiber and Graphite-reinforced plastic).
Pebble bed nuclear reactors use a coating of pyrolytic carbon as a neutron moderator for the individual pebbles.
to coat graphite cuvettes (tubes) in graphite furnace atomic absorption furnaces to decrease heat stress, thus increasing cuvette lifetimes.
several applications in electronic thermal management: thermal interface material, heat spreaders (sheets) and heat sinks (fins)
to fabricate grid structures in some high power vacuum tubes.
as a monochromator for neutron and x-ray scattering studies.
Radial Head Prosthesis
in Automotive industries where a desired amount of friction is required between two components
Highly Ordered Pyrolytic Graphite (HOPG) is used as the dispersive element in HOPG spectrometers which are used for X-ray spectrometry.

Pyrolytic carbon is generally grown by the pyrolysis of hydrocarbons, either on surfaces by chemical vapor deposition or in porous materials by chemical vapor infiltration. Despite the industrial importance of pyrolytic carbon materials, and the numerous studies reported on their structure, aspects of the growth mechanism remain elusive. pyrolytic carbon materials are generally classified as being optically isotropic or anisotropic, with the anisotropic form being the more attractive for most applications. The relationship between the structure of anisotropic pyrolytic carbon and the growth conditions has been extensively studied, and a number of key factors have been recognized to influence the pyrolytic carbon structure', including: the hydrocarbon precursor; pressure; temperature; residence time; and surface morphology³⁻⁶. The structure of pyrolytic carbon has also been the focus of numerous reports¹. The anisotropic form is of particular interest, being comprised of columnar structures and growth cones of various sizes, which usually emanate from the substrate surface.

In 1964 two reports, one by Coffin and the other by David et al., proposed differing theories to account for the formation of these structures^{4,5}. Images from these original reports, showing typical growth cones, are presented in FIG. 1. David proposed that the growth cones form from spherical carbon “germs” and grow from the substrate surface, whereas Coffin rationalized the growth on the basis of layered deposition over surface asperity. To date, neither these, nor any new theories appear to have been generally accepted. The theory proposed by Coffin is inconsistent with aspects of the structure of pyrolytic carbon. In particular, it doesn't explain the grain boundaries between columns, nor is it clear why all surface roughness (presumably with a range of different morphologies) would produce similar hyperboloid-shaped structures in cross-section. Despite the apparent weaknesses in this theory it is still invoked to explain the formation of the growth cones^{2,7,8}. In contrast, the theory of David appears to have been disregarded for the last three decades. One possible reason for this is that, although noting that surface roughness promoted the formation of larger “growth cones”, the authors did not demonstrate how their proposed mechanism accounted for this. While the theory was not generally accepted, aspects of the theory have been verified in other studies. In particular, several recent studies of the initial stages of pyrolytic carbon deposition have reported that anisotropic pyrolytic carbon growth begins with the formation of isolated deposits that rapidly coalesce^{3,6,9}. Granular layers, often comprised of spherical structures, have also been observed at substrate/pyrolytic carbon interfaces^{6,8}.

Commercial production of pyrolytic carbon of consistent, reproducible crystalline character may be produced in a fluidized bed, where good quality has been found to be dependent upon maintaining the temperature, the hydrocarbon partial pressure, the bed surface area and the contact time at constant values. Thus, in order to compensate for changes that would inevitably occur in the total surface area of a dynamic system in a fluidized bed pyrolytic carbon coater, it was felt necessary to always make adjustments in the number of ancillary particles in the bed.

U.S. Pat. No. 6,274,191 addresses the problem of precise regulation of pyrolytic carbon coating to provide even better control of pyrolytic carbon deposition and growth, particularly for the making of components for medical devices, such as heart valves, wherein reproducibility and precision are considered to be of utmost importance. While this process has partially addressed this problem, there is still a need for the structure and properties of pyrolytic carbon to be better controlled to further improve current production techniques and open up new application fields.

### SUMMARY OF THE INVENTION

In a first aspect of the present invention, there is provided a process for the production of pyrolytic carbon comprising the steps of:
(A) depositing pyrolytic carbon on a substrate; and
(B) controlling the structure of the deposited pyrolytic carbon through use of a Volmer-Weber island (V-W) growth model.

With an understanding of the role of the V-W growth model in pyrolytic carbon formation it is possible to identify the factors that will control the structure of the pyrolytic carbon formed. As a result, the strength, wear resistance, hardness, flexibility and density of the pyrolytic carbon structure can be also controlled.

Dependent upon the deposition means, the pyrolytic carbon deposits may have anisotropic or isotropic microstructures with columnar or grainy structures. Preferably, the deposited pyrolytic carbon comprises columnar structures possessing anisotropic properties.

Within one embodiment, it has been found that four main factors may be manipulated to control the shape and cross-sectional area of the columns within an anisotropic pyrolytic carbon deposit formed on a surface. These properties are:
a. the rate of nucleation;
b. the rate of growth;
c. the portion of the substrate surface elevated above a base substrate.

The term “manipulation” will be understood to mean the adjustment of a parameter in order to achieve a desired result. In the context of the present invention, the manipulation will be performed with the benefit of the Volmer-Weber island growth model to achieve the desired result. Preferably, the Volmer-Weber island growth model forms the basis of a computer simulation program to enable the consequence of parameter adjustments to be simulated and thus enable optimal adjustments to be performed.

The first two of these factors are determined by the nature of the substrate and the gas-phase growth conditions, the third by the substrate surface. In the case of chemical vapour infiltration of porous media the situation is more complex due to growth occurring in many directions, however the same basic principles of the V-W island growth mechanism can still be applied. With this knowledge the design of pyrolytic carbon structures that, in combination with control of other growth factors identified from the V-W island growth model, will produce pyrolytic carbon with the desired structure, and hence physical properties. FIGS. 7 and 8 illustrate how the surface of the substrate may be modified to increase the grain size of the pyrolytic carbon.

Preferably, the structures are thin films and coatings. Alternatively, the pyrolytic carbon may in the form of fibers or any other structure capable of being formed from pyrolytic carbon derived from a vapour phase, including, for example, porous 2-D planar-random carbon-carbon (c-c) composite perform densified using chemical vapour infiltration (CVI) of pyrolytic carbon.

For convenience and readability, pyrolytic structures may be referred to as coatings or films. However, it would be understood that such references to the pyrolytic structure are not limited to these embodiments.

Preferably, the pyrolytic carbon structures are anisotropic.

The substrate comprises nucleation sites from which nuclei form and grow. Sites on a surface which have a relatively low free energy preferentially form nucleation sites. At such preferential sites, the effective surface energy is lower, thus diminishing the free energy barrier and facilitating nucleation. The nucleation site may be phase boundaries or impurities like dust or soot and requires less energy than homogeneous nucleation.

Preferably, at least a portion of the nucleation sites on the substrate are predetermined in frequency and location.

Preferably, the structure of the deposited pyrolytic carbon is controlled by the manipulation of a portion of the substrate surface elevated above a base substrate surface. In the case of the manipulation of the substrate surface, it will be understood that this manipulation is preferably performed during the design and manufacture stage of the substrate.

The portion of elevated substrate surface is preferably in the range of 0.01% to 50%, more preferably in the range of 0.1% and 30%, even more preferably in the range 1% to 20% and yet even more preferably in the range 2% and 10% of the total surface of the substrate.

Preferably the individual portions of the elevated substrate surface (i.e. protrusions) have a surface area of between 0.1 μm² to 1 cm², more preferably between 1 μm² to 100000 μm² and even more preferably between 10 μm² to 1000 μm².

In some embodiments, the surface area of the elevated substrate is kept as small as practical (i.e. in light of manufacturing constraints and structural integrity) to minimize the number of competing nuclei growths to thereby increase the grain size of the pyrolytic carbon growths (and thus increase the wear resistance of the coated substrate).

Through manipulating a portion of the substrate surface elevated above a base substrate surface, pyrolytic carbon emanating from the nucleation sites on the elevated surface dominate the coating structure relative to the pyrolytic carbon emanating from the base surface of the substrate. Consequently, through controlling the proportion of elevated nucleation sites (i.e. preferential nucleation sites), the resultant structure of the pyrolytic carbon may also be controlled.

Importantly, the surface of the substrate may be manipulated such that this parameter dominates the structure of the pyrolytic carbon relative to the other parameters such as the rate of nucleation or the rate of growth of the pyrolytic carbon. Thereby, through understanding the Volmer-Weber island growth model, substrates may be developed which enable the production of a more consistently structured pyrolytic carbon coating, film or structure.

The elevated surface is preferably a plurality of protrusions emanating from a base surface of the substrate.

In some embodiments the protrusions are arranged in a geometric pattern on the base surface of the substrate. The geometric pattern may be such that the elevated nucleation sites are substantially equidistance apart. Alternatively, the geometric pattern may vary according to the geometry of the substrate surface or the functionality of the substrate. For example, if a portion of the substrate is required to be exposed to a relatively high degree of vibration compared to another portion of the substrates then the grain size of the pyrolytic carbon in this portion may be reduced through reducing the relative proportion of elevated nucleation sites in this area.

The protrusions are preferably spaced (on average) at least 1 μm, more preferably 20 μm apart, even more preferably at least 50 μm and yet even more preferably at least 100 μm apart. The maximum distance between protrusions is preferably less than 1 cm, although the exact spacing will be dependent upon a number of parameters including the height of the elevated nucleation sites and the thickness of the pyrolytic carbon coating or structure. Indeed, the distance between the protrusions is preferably calculated with aid of the Volmer-Weber island growth model.

To increase the proportion of elevated nucleation sites, the elevated surface is preferably configured to promote the preferential formation of nucleation sites relative to a base surface of the substrate. This may be achieved through texturing the elevated surface to thereby create a plurality of sites which have a relatively low free energy and thus preferentially form nucleation sites.

The elevated portion is preferably at least 100 nm and no more than 1 cm above a base surface of the substrate, more preferably at least 10 μm and no more than 1000 μm above a base surface of the substrate and even more preferably at least 50 μm and no more than 500 μm above a base surface of the substrate. The required elevation is influenced by the rate of nucleation, with relatively low elevations (e.g. 100 nm) still able to influence the structure of the pyrolytic carbon if the nucleation rate is sufficiently high. The Volmer-Weber island growth model will be able to simulate the impact of the elevation high at various nucleation rates.

This distance of the elevated portion above the base surface also dictates the relative distance between the nucleation sites on the base surface of the substrate and the elevated nucleation sites. The more elevated the nucleation site is from the base surface, the more the pyrolytic growth emanating from the elevated nucleation sites dominates the structure compared to the pyrolytic carbon emanating from nucleation sites from the base surface of the substrate.

In one embodiment, the location and frequency of the elevated nucleation sites is manipulated such that the pyrolytic carbon structure over the substrate is substantially determined by the elevated nucleation sites.

It is counter-intuitive to deliberately create nucleation sites on a substrate in order to increase the grain size of the pyrolytic carbon formations.

In one embodiment, the Volmer-Weber 3D island growth model comprises the following contraints:
a. nucleation sites are randomly distributed on a flat surface at a constant rate per unit area;
b. once a nucleus is generated it grows at a constant radial growth velocity in free (non-occupied) directions; and
c. nucleation sites accumulate only on the substrate.

In an alternative embodiment, the Volmer-Weber 3D island growth model comprises the following constraints:
a. nucleation sites are preferentially distributed on the elevated substrate at a constant rate per unit area;
b. once a nucleus is generated it grows at a constant radial growth velocity in free (non-occupied) directions; and
c. nucleation sites accumulate only on the substrate.

Various other constraints may be placed upon the Volmer-Weber 3D island growth model to correlate the computer simulated pyrolytic carbon structure to outcomes to those observed in practice. Preferably, the model is refined using empirical data gained from analysis of the coated substrate (or other structure) product versus the operating conditions under which the product was formed.

Through the use of varying constraints, the model may be suitably used to generate a computer simulation to predict the most suitable substrate surface designs for a required pyrolytic carbon structure.

In a second aspect of the present invention, there is provided a substrate for receiving a pyrolytic carbon coating as previously defined in the first aspect. It will be understood that this technical features of this substrate may not be dependent upon the use of the Volmer-Weber 3D island growth model (i.e. it may be independent of process features).

In one embodiment, there is provided a substrate for receiving a pyrolytic carbon structure comprising an elevated surface portion, wherein the elevated surface is in the range of 0.01% to 50% of the total surface of the substrate.

Preferably, the elevated surface is a plurality of protrusions emanating from a base surface of the substrate. Preferably, the protrusions are arranged in a geometric pattern on the base surface of the substrate. The elevated surface is preferably configured to promote the preferential formation of nucleation sites relative to a base surface of the substrate.

In a third aspect of the present invention, there is provided a pyrolytic carbon coated substrate comprising the substrate as described in the second aspect. Preferably, the ratio of the height of the elevated portion of the substrate to the base surface of the substrate to the height of the pyrolytic carbon coating to the base surface of the substrate is at least 0.05 and no more than 0.5. More preferably said ratio is at least 0.1 to no more than 0.4 and even more preferably said ratio is at least 0.15 to no more than 0.3. Through, have the elevated portion of the substrate within this range, the portion of elevated nucleation sites is sufficient for this parameter to significantly impact, if not dominate, the pyrolytic carbon structure.

The thickness of the pyrolytic carbon coating is preferably in the range of 2 μm to 50,000 μm, more preferably in the range of 10 μm to 1,000 μm and even more preferably between in the range of 100 μm to 600 μm.

In a forth aspect of the present invention there is provided medical implants comprising the pyrolytic carbon coated substrate as described in the third aspect.

In a fifth aspect of the present invention, there is provided use of the substrate of the second aspect in the manufacture of a pyrolytic carbon coated substrate.

### Volmer-Weber 3D Island Growth Mechanism

The Volmer-Weber 3D island growth model or mechanism (also referred to as the Volmer-Weber island growth model, the V-W growth or the V-W island growth model) is well defined in the literature, with mathematical models and associated algorithm readily available to the artisan within this field. For example, a comprehensive mathematic model may be found in Trofimov, V. I. Morphology evolution in a growing. Thin Solid Films 428, 56-65 (2003), which is wholly incorporated into this specification by cross reference. For the purposes of the present invention the Volmer-Weber 3D island growth mechanism or model will preferably encompass the Stranski-Krastanov growth mechanism. In embodiments in which the substrate is graphite, the person skilled in the art would recognize that the Stranski-Krastanov growth mechanism has particular relevance and similarities with the Volmer-Weber 3D island growth model.

With the use of a mathematical model which is representative of the V-W island growth mechanism, the growth and characteristics of anisotropic pyrolytic carbon can be simulated to thereby optimize formation conditions to enable the structure and characteristics of pyrolytic carbon to be tailored to the needs of a specific application.

The models have been able to establish, for instance that “growth cones” are simply large columnar structures, or collections of columnar structures, produced by V-W growth on surface asperity.

For the purposes of the present invention, an elevated surface is a portion of the surface which covers the apex of a protrusions emanating from the base of the substrate. The apex covers the top of the elevated surface when the elevated surface is substantially flat relative to the base surface and covers the surface area from apex to a distance of 90% elevation between the base surface and the apex, when the elevated surface in not flat (e.g. a pyramid or cone or Gaussian hump etc).

### DESCRIPTION OF THE FIGURES

The patent or application file contains at least one drawing executed in color. Copies of this patent or patent application publication with color drawing(s) will be provided by the Office upon request and payment of the necessary fee.

FIG. 1 are SEM images of columnar structures in the cross-section of anisotropic Pyrolytic carbon deposits from the prior art of David et al. (a)⁵, and Coffin (b)⁴.

FIG. 2 are SEM images of: (a) a continuous carbon deposit on a zirconia surface; (b) a non-continuous carbon deposits on zirconia view from above; (c) a similar deposit to that shown in (b) but viewed at an angle of 40° to the zirconia surface (Inset—A SEM image of the cross-section of a hemispherical carbon deposit sliced by FIB milling).

FIG. 3 are SEM images of non-continuous carbon structures (axial position along the reactor=ca. 700 mm, radial position in the reactor=center; temperature=1070 K, T=0.017 s). (a) A SEM image of the cross-section of a hemispherical carbon structure sliced by FIB milling. (b) A SEM image of a mechanically damaged carbon structure. (c) A SEM image of the underside of a deposit that had been forcibly detached from the substrate surface and lying upturned on the wafer surface (an undetached film is visible underneath).

FIG. 4 is a schematic diagram of a time sequence for growth by the V-W mechanism: (a) represents a stage at which most deposits are individual hemispherical islands; (b) represents a stage at which the hemispherical islands have begun to impinge and coalesce; (c) represents a stage shortly after the islands have coalesced and a continuous film has formed. Upper images represent the view from perpendicular to the ceramic surface and lower images represent a cross-section along the surface (A-A). Each shade of grey represents a carbon structure grown from an individual nucleus. Red represents the substrate and blue the vapor above. For all simulations the box shown represents a box of 1×1×1 units of length, and 1 unit of time is defined as the time it takes for a deposit to grow 1 unit of length. Therefore the radial growth velocity is 1 unit of length/unit of time. For this simulation the seeding rate was set to 2×10² nuclei/unit length²/unit time.

FIG. 5 is a schematic representation of a time sequence for growth by the V-W mechanism with a density of nuclei ca. 1000 times greater than that for FIG. 4: (a) represents a stage at which most deposits are individual hemispherical islands; (b) represents a stage shortly after all islands have coalesced and a continuous film has formed; (c) represents a mature stage of growth at which the columns from nuclei formed early in the growth period have come to dominate the structure. Each shade of grey represents a carbon structure grown from an individual nucleus. Red represents the substrate and blue the vapor above.

FIG. 6 is a simulated cross-section of a film grown by the V-W island mechanism. Each shade of grey represents a carbon structure grown from an individual nucleus. To represent layered carbon growth the red lines show the deposit surface at periodic growth intervals.

FIG. 7 is a schematic of growth by the V-W mechanism over surfaces with different roughness, at a mature stage of growth (seeding rate=2×10⁶ nuclei/unit length²/unit time): (a) growth over a flat surface; (b) growth over a single cylindrical-shaped protrusion on a flat surface; (c) growth over a single cylindrical-shaped protrusion, twice the height of the protrusion shown in (b), on a flat surface; (d) growth over a single Gaussian hump-shaped protrusion, the same height as the protrusion shown in (c), on a flat surface. For each simulation the nuclei were seeded at the same time and position. Blue columns represent growth from nuclei seeded on the top of the cylinders, or within the top 30% of the Gaussian hump.

FIG. 8 is a schematic of growth by the V-W mechanism over surfaces with different roughness, at a mature stage of growth (1×10⁸ nuclei/unit length²/unit time): (a) growth over a flat surface; (b) growth over two protrusions, one higher than the other; (c) growth over multiple periodic protrusions. For each simulation the nuclei were seeded at the same time and position.

FIG. 9 is a schematic diagram of the results of computer simulations of pyrolytic carbon growth by the Volmer-Weber 3D island growth mechanism on three different surfaces. In each case the position and timing of nucleation was identical. LHS images show a cross-section of the material and RHS images show the view from above. Each shade of grey represents a carbon structure grown from an individual nucleus seeded on the substrate. Each shade of red represents a carbon structure grown from an individual nucleus seeded on the protrusion. Green represents the substrate and blue the vapor above.

FIGS. 10 and 11 are a schematic diagram of the results of computer simulations of pyrolytic carbon growth by the Volmer-Weber 3D island growth mechanism on three evaluated flat surfaces (FIG. 10) and three Gaussian shaped protrusions (FIG. 11) of progressively increasing apex surface area. Each shade of grey represents a carbon structure grown from an individual nucleus seeded on the substrate. Each shade of red represents a carbon structure grown from an individual nucleus seeded on the protrusion. Green represents the substrate and blue the vapor above.

FIGS. 12, 13 and 14 are schematic diagrams of the results of computer simulations of pyrolytic carbon growth by the Volmer-Weber 3D island growth mechanism illustrating the effect of substrate surface or nucleation rate on the structure of the pyrolytic carbon.

### DETAILED DESCRIPTION OF PREFERRED EMBODIMENTS

Pyrolytic carbon is preferably deposited onto a suitable substrate by the thermal decomposition of a gaseous hydrocarbon at high temperature, using a process called Chemical Vapor Deposition (CVD). CVD is a very versatile process used in the production of coatings, powders, fibers and monolithic parts.

With CVD, it is possible to produce almost any metallic or non-metallic element, including carbon and silicon, as well as compounds such as carbides, nitrides, borides, oxides, and many others. A key advantage of the CVD process lies in the fact that the reactants used are gases, thereby taking advantage of the many characteristics of gases. One result is that CVD is not a line-of-sight process as are most other plating/coating processes.

Graphite has properties that are particularly well suited for pyrolytic carbon coating, most notably its thermal expansion coefficient that avoids weakening the coated substrate. In order to appear visible on X rays, graphite is soaked in tungsten. This permeation does not change the mechanical properties of the substrate.

For example, to make pyrolytic carbon coated orthopedic implants, a graphite substrate is introduced into a chamber that is heated to between 1,200° and 1,500° Celsius. A hydrocarbon gas, typically propane, is introduced into the chamber. These high temperatures facilitate the decomposition of the hydrocarbon precursor via a complex radical cascade, producing a variety of carbon containing species which can participate in pyrolytic carbon deposition onto the graphite substrate. Over a period of time the substrate is completely coated with between 300 and 600 microns of pyrolytic carbon. Reaction byproducts are then exhausted out of the system.

Pyrolytic carbon may be formed in a fluidized bed furnace
The bed consists of small ceramic particles and parts to be coated
A levitating gas creates required random motion of parts within the bed
Heating elements raise furnace temperature to 1000°-1500° C.
An introduced hydrocarbon gas undergoes decomposition at these temperatures creating species that deposit on the surface of the substrate.

Further details relating to the process of applying a pyrolytic coating to a substrate may be readily found in the prior art including U.S. Pat. No. 6,274,191.

### Example 1

A gas flow control and mixing panel was supplied with methane (Linde, 99.95%), oxygen (Linde, 99.9%) helium (BOC, 99.99%) and argon (BOC, 99.99%). The gas flow rates were controlled by mass flow controllers (Brooks 5850E) operating within the range of 10-90% of their total flow. The mass flow controllers were calibrated using a Bios Definer 220 flow meter and calibration curves were checked for linearity. Feed gases were blended prior to being introduced into the reactor. The pressure was monitored at the inlet and outlet of the reactor by pressure transducers. The feed and product streams were analysed by gas chromatography using an on-line Shimadzu GC17A chromatograph set up with two flow lines. A gas sample was simultaneously injected into the two flow lines. One flow line flow line, setup with a Varian CP-Molsieve 5A column (25 m, 0.53 mm, 50 μm) and a thermal conductivity detector, provided analyses of helium, hydrogen and oxygen. The second flow line, equipped with a Varian CP-PoraPLOT Q column (27.5 m, 0.53 mm, 20 μm), methaniser and flame ionisation detector, was used for the analysis of carbon dioxide, carbon monoxide and C₁-C₃ hydrocarbons. Analyses were conducted under isothermal conditions at 30° C.

A reactor tube comprised of zirconia with 10.5% yttria was stacked with wafers of zirconia with 6% scandia (Ceramatec) and heated to 1673K under a flow of argon¹². Once the temperature had stabilized methane (1%) and dioxygen (CH₄: O₂=1.1) were introduced into the feed (total flow=5000 sccm) and this flow was maintained for a period of 240 minutes. During this time the product gas composition was analyzed periodically by gas chromatography (GC). After 240 minutes the reactive components were removed from the feed and the argon flow rate was reduced to 150 sccm. The reactor was cooled to ambient temperature and the wafers were removed for analysis.

The surfaces of the zirconia wafers were analyzed by scanning electron microscopy (SEM; FE-SEM Philips XL30 and FEI Helios Nanolab 600 FIB-SEM) combined with energy disperse X-ray (EDX) analysis and micro-Raman spectroscopy (Reinshaw Invia, λ₀=514.5 nm).

A longitudinal temperature profile within the reactor was measured using an S-type thermocouple, under identical conditions to the experiment, but without wafers inside the reactor.

The surface area to free volume ratio (NV) in the section of the reactor stacked with wafers was 1.13 mm⁻¹

We have defined residence times, T, as the time that the gas phase was exposed to temperatures above 1300 K, as little reactivity was observed below this temperature. Using this definition the total residence time was 0.015 s.

### Results

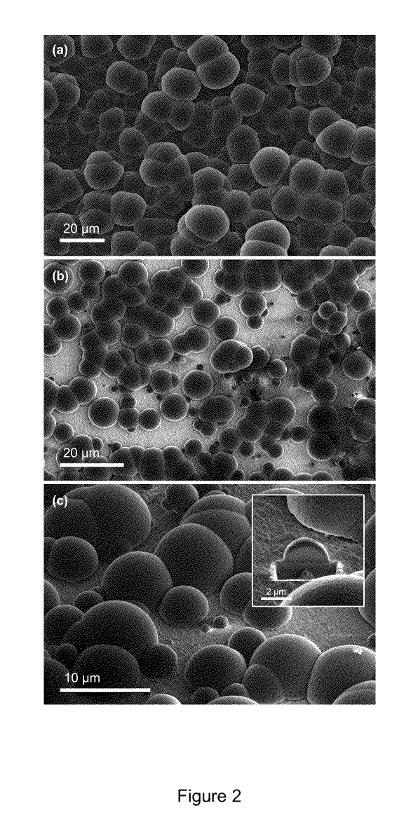

SEM examination of the surface of the zirconia wafers showed the presence of carbon deposits that resembled Johnson-Mehl tessellations, with polygonal elements with triple-point grain boundaries (FIG. 2a). Some areas of the ZrO₂ surface were not covered by a continuous film, but rather by non-continuous carbon deposits, as shown in FIGS. 2b and c. These deposits were either isolated carbon hemispheres or non-continuous Johnson-Mehl tessellations.

A number of isolated hemispherical deposits were sliced by FIB milling and the resulting cross-sections examined by SEM. One such cross-section is shown as an inset in FIG. 2c. The appearance of these cross-sections supported the assessment that the deposits were hemispheres, and EDX analysis showed that they were comprised of solid carbon.

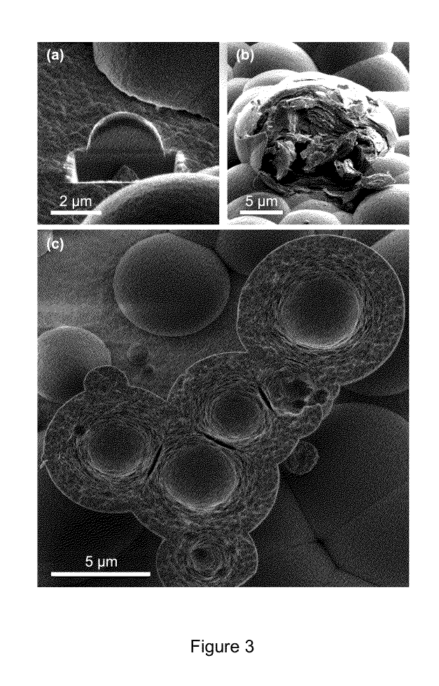

Because of the likelihood that the FIB milling technique had changed the internal structure of the deposits, the inside of a deposit that had been mechanically damaged was examined and appeared to be comprised of concentric layers of carbon (FIG. 3b). The concentric arrangement of the carbon layers was also evident when the underside of a deposit was analyzed. A zirconia surface bearing carbon deposits was scraped with a sharp blade and on examination by SEM an upturned deposit was observed (FIG. 3c). It appeared that on breaking from the substrate the deposit had fractured. Our interpretation of this image is that on breaking from the surface the central area of some grains remained on the surface, leaving hemispherical-shaped cavities in the underside of the center these grains. This interpretation was difficult to verify as the central areas that are proposed to remain on the surface would be expected to be similar in appearance to small hemispherical deposits.

Grain boundaries were clearly evident between adjacent grains. In some cases there appeared to be a void along the grain boundary, however we could not determine whether this was a feature of the structure or had formed as a consequence of breaking the deposit from the zirconia surface.

The nature of the carbon structure was examined using micro-Raman spectroscopy. From the Raman spectra the I_{D}/I_{G} ratio was found to be ca. 1.6, consistent with graphite with a low degree of order.

These observations are consistent with growth by the V-W mechanism. Growth via this mechanism has been well described with comprehensive mathematical models¹³, however, for our purposes a simple model was developed to investigate the consequences of this mechanism on the structure of pyrolytic carbon materials.

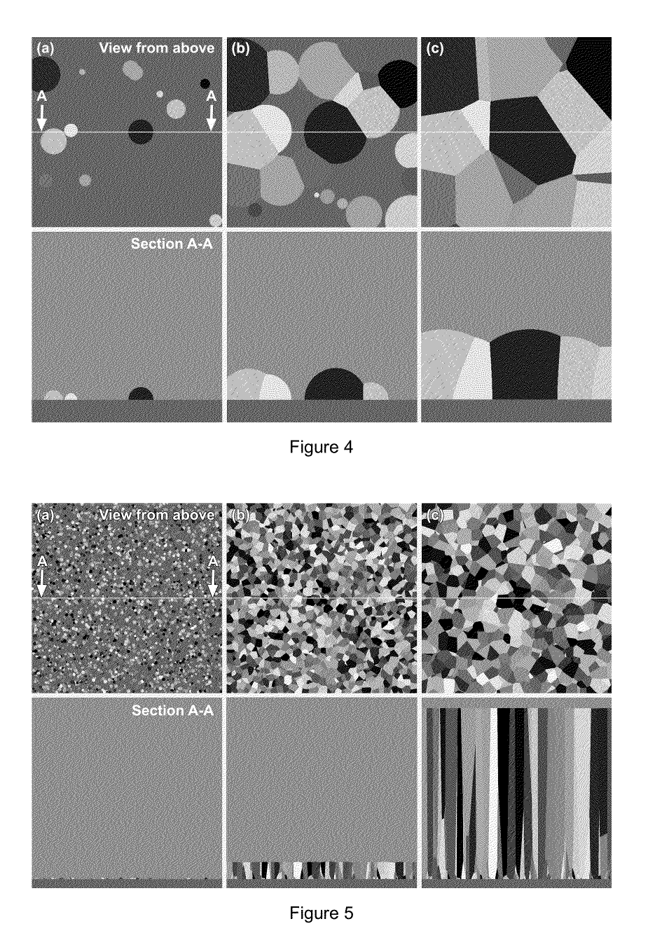

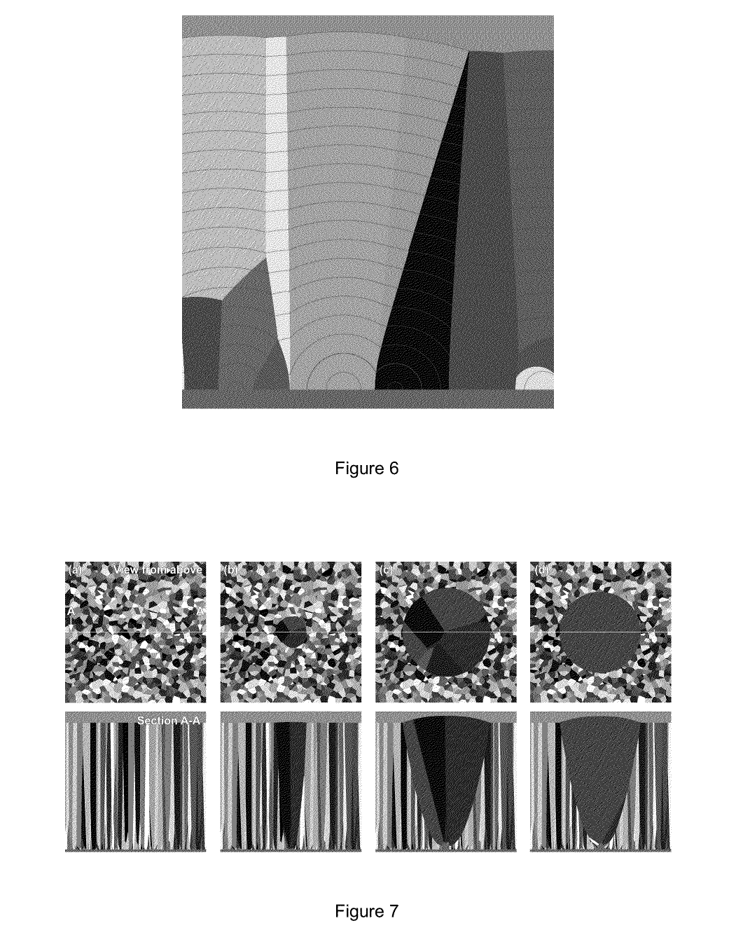

The simplified model defined a V-W mechanism which seeds nuclei randomly on a flat surface at a constant rate per unit area and once a nucleus is generated it grows at a constant radial growth velocity in free (non-occupied) directions. Within this embodiment, seed points accumulate only on the substrate. A time sequence generated using this model is presented in FIG. 4.

This model generates all characteristic morphological features of the deposits observed in this study. The pyrolytic carbon growth was interrupted prior to coalescence of the hemispherical islands due to a relatively low nucleation density and a slow rate of growth. We postulated that growth by the V-W mechanisms may be common, but the initial stages are seldom seen due to higher densities of nucleation sites resulting in rapid film formation. The model was used to investigate this by increasing the nucleation site density by ca. 1000. Under these conditions rapid coverage of the substrate surface was shown to occur (FIG. 5).

In addition, with the higher nucleation density the effect of the growth mechanism on the structure of the material also became apparent. From the cross-section in FIG. 5c, it is clear that the structure is columnar. This is consistent with numerous experimental reports of the structure of anisotropic pyrolytic carbon^{4,7,8,14-17}. It can also be seen that the number of elements (i.e. the top of columns) in the tessellated surface decreases with film growth, as described previously⁵. This is a consequence of the constant rate of nucleation. For any two neighboring columns, the column that originated for the earliest seeded nuclei impinges on the column seeded later. Consequently, columns based on the earliest forming nuclei progressively dominate the structure over time by terminating the growth of columns seeded later. This is most obvious in the early stages of growth where the cross-sectional structure of the deposit looks somewhat disordered due to the rapid termination of columns originating from the latest formed nuclei (see the cross-section in FIG. 5 b). This behavior accounts for the observation of “granular” regions at pyrolytic carbon/substrate interfaces^{6,8}.

The formation of grain boundaries between columns is also consistent with V-W growth. For each column the graphitic layers are oriented concentrically around its seed point, thus the layers in adjacent columns are misaligned. This can be seen in the results for the simulation shown in 6, in which red lines, that indicate the surface of the deposit at periodic growth intervals, show the arrangement of carbon layers in the structure.

Another structural feature of anisotropic pyrolytic carbon, often described in the literature, is the presence of growth cones that result from surface asperity. The simple model of V-W growth was applied to surfaces with surface texture or roughness (FIG. 7). Four situations were compared: a flat surface (a) (i.e. the base surface of the substrate); surfaces with single cylindrical-shaped protrusions of different heights (b and c); a surface with single Gaussian hump-shaped protrusion (d).

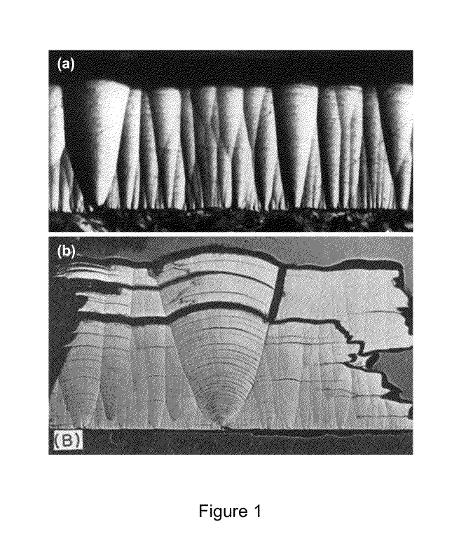

The hyperboloid structures above the protrusions in b, c and d demonstrate that V-W growth over surface asperity can form growth cones such as those reported (see FIG. 1). The columns formed from these nuclei have a similar advantage to those that are formed earlier (vide supra). During the growth of the film they impinge on the neighboring columns of nuclei formed lower. Comparison of b and c shows that the higher above the substrate nuclei are formed the more privileged, and hence larger, is the resulting growth cone. A simple check of the literature confirms this, whenever the base of a growth cone is visible (note: this is not always the case in cross-sections), the largest cone grows from the highest point on the substrate, for example see FIG. 1 [4, 5, 18]. A consequence of the growth cone impinging on surrounding columns is that the column or columns in the growth cone have a larger cross-sectional area than the columns from nuclei seeded lower. Thus a pyrolytic carbon deposit with growth cones will have fewer grain boundaries in the mature film than one without.

In the example shown in FIG. 7 (d) the protrusion on the surface is a Gaussian hump with the same height as the cylinder in (c). Comparison of the two cases shows that the shape of the protrusion may affect the shape of the growth cones, in each case the shape of the cross section is a hyperbola. In particular, the elevated surface or the Gaussian hump (d) has a narrower apex which results in fewer nucleation sites (and hence fewer seeded nuclei) from which pyrolytic carbon growth (i.e. columns or cones) is able to impinge on the growth of columns emanating from the base of the substrate surface (a) in addition to pyrolytic carbon growth from beneath the apex of the elevated portion of the protrusion. As a result, an elevated substrate with a smaller number of preferential nucleation sites result in larger grained pyrolytic carbon growth. In this example (d) the growth cone consists of one column at the surface of the elevated substrate.

The other main factor influencing the shape of the growth cone is the height of the protrusion above the plane of the substrate.

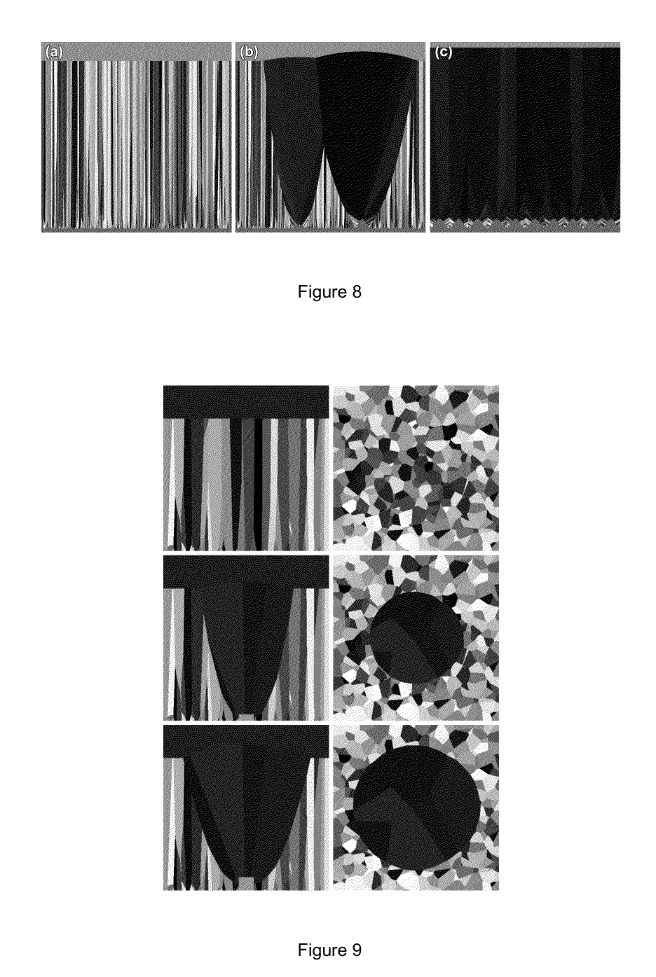

An important consequence of the V-W mechanism is that surface texture or roughness will have a significant effect on the structure of the growth columns formed. FIG. 8 shows the result of a simulation of growth over a flat surface (a), a surface with two protrusions with different heights (b), and a surface with periodic protrusions of the same height (c). The example of two protrusions demonstrates that growth cones seeded higher dominate and impinge on growth cones seeded lower. Because growth cones and columns are one and the same, this is in essence the behavior as described previously for columns impinging on columns and growth cones impinging on columns. The relationship between columns and growth cones appears to have been a point of confusion in the literature. Although we are continuing to use the term “growth cone” to describe the structures produced above protrusions, it is important to recognize that these are simply dominant columns, or collections of columns.

In the case of periodic protrusions the columns formed from higher nuclei are less privileged than the example of a single protrusion. This results in fewer growth columns at the surface than the case of no substrate roughness (a), and columns with a smaller cross-sectional area than that of the large growth cone formed in the case of a single protrusion (b-d). The results of this computer simulation model highlight the benefits of using the computer simulation model designing a patterned series of protrusions sufficiently separated to result in the desired grain size, which in turn produce the desired mix of functional properties of the pyrolytic carbon structure.

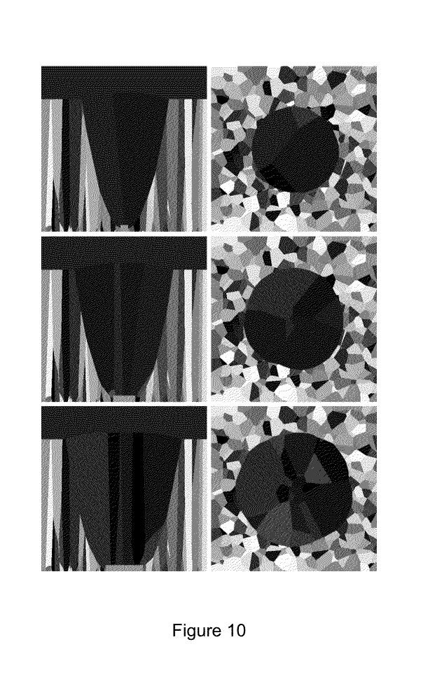

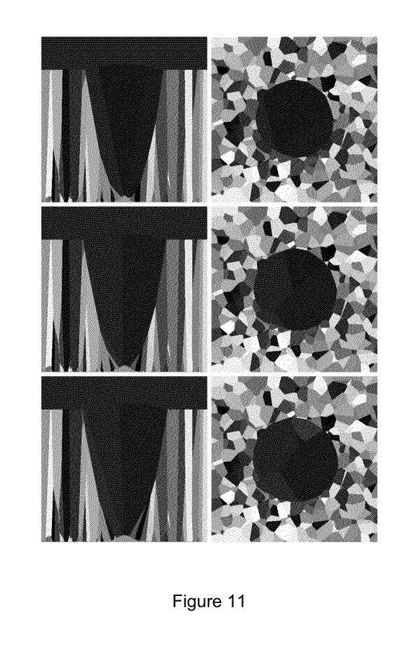

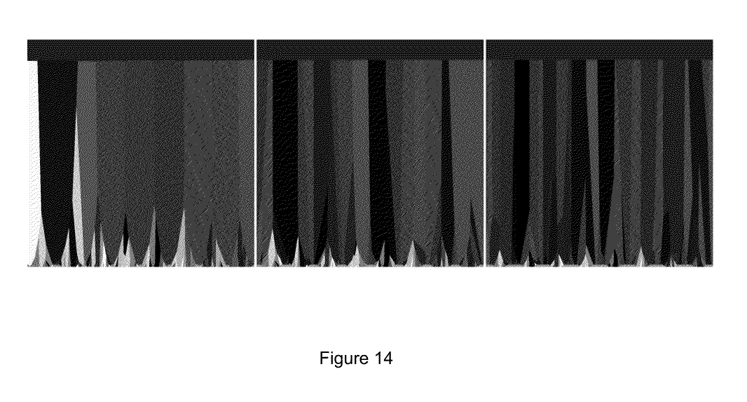

FIGS. 9 to 11, 13 and 14 further illustrate the effect of the protrusion shape (height and elevated surface area) on the structure of the pyrolytic carbon.

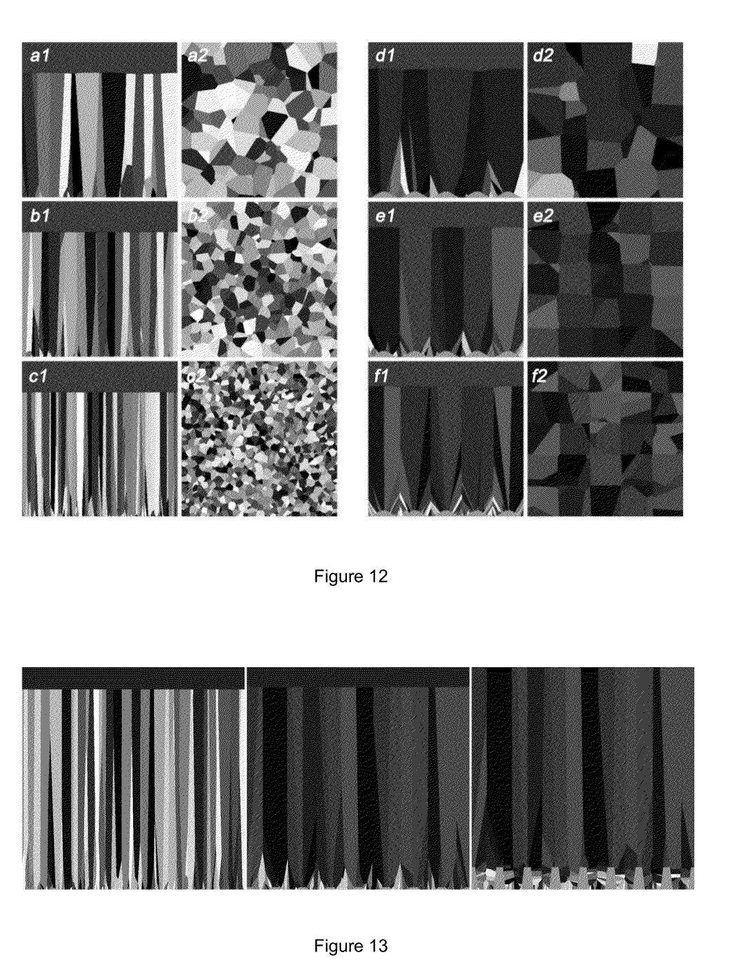

FIG. 12 illustrates how increasing nucleation density (Figures a1 to c1 and Figures d1 to f1) influence the resultant pyrolytic carbon structure. For a flat substrate surface (Figures a1 to c1) a larger structural variation is observed relative to a substrate comprising a plurality of protrusions (Figures d1 to f1). This demonstrates that through manipulation of the substrate surface, variations in process conditions which may lead to increased nucleation density (e.g. changes in temperature and/or pressure) may be significantly negated, in terms of their impact on the resultant pyrolytic carbon structure.

By considering the action of V-W growth in anisotropic pyrolytic carbon formation it is possible to identify the factors that will control the columnar structure. Three factors will control the shape and cross-sectional area of the columns within an anisotropic pyrolytic carbon deposit formed on a surface: the rate of nucleation; the rate of growth; and the texture of the surface (nucleation site height distribution over the surface). The first two of these factors will be determined by the nature of the substrate and the growth conditions, and the third by the substrate surface. Although controlling each of these factors is not trivial, with an understanding of the mechanism of pyrolytic carbon growth it is possible that rational strategies can be devised to produce pyrolytic carbon materials with desired structures and properties.

Clearly the growth cones and columnar structures are a consequence of the same mechanism. This appears to have been a point of confusion in the prior art.

### REFERENCES

1 Oberlin, A. Pyrocarbons. Carbon 40, 7-24 (2002).
2 Delhaes, P. Chemical vapor deposition and infiltration processes of carbon materials. Carbon 40, 641-657 (2002).
3 Bouchard, E., Lavenac, J., Roux, J. C., Langlais, F. & Delhaes, P. Pyrocarbon deposits on a graphite surface observed by STM. Chem. Vapor Depos. 7, 125-130 (2001).
4 Coffin, L. F. Structure-property relations for pyrolytic graphite. J. Am. Ceram. Soc. 47, 473-478 (1964).
5 David, C., Sublet, P., Auriol, A. & Rappeneau, J. Properietes Structurales des carbones pyrolytiques deposes entre 1000-degrees-C. et 1800-degrees-C. Carbon 2, 139-148 (1964).
6 De Pauw, V. et al. Dependence of pyrocarbon microstructure on the substrate and annealing during the initial stage of chemical vapor deposition. Carbon 46, 236-244 (2008).
7 Lopez-Honorato, E., Meadows, P. J. & Xiao, P. Fluidized bed chemical vapor deposition of pyrolytic carbon—I. Effect of deposition conditions on microstructure. Carbon 47, 396-410 (2009).
8 Bourrat, X., Fillion, A., Naslain, R., Chollon, G. & Brendle, M. Regenerative laminar pyrocarbon. Carbon 40, 2931-2945 (2002).
9 Pfrang, A., Wan, Y. Z. & Schimmel, T. Early stages of the chemical vapor deposition of pyrolytic carbon investigated by atomic force microscopy. Carbon 48, 921-923 (2010).
10 Oura, K., Lifsic, V. G., Saranin, A. A., Zotov, A. V. & Katayama, M. Surface science: an introduction. (Springer, 2003).
11 Bauer, E. Phaenomenologische Theorie der Kristallabscheidung an Oberflaechen I. Zeitschrift fur Kristallographie 110, 372-394 (1958).
12 Lee, W. J. et al. Microstructure formation on exposure of silicon carbide surfaces to the partial oxidation of methane. Catalysis Today 178, 85-97 (2011).
13 Trofimov, V. I. Morphology evolution in a growing film. Thin Solid Films 428, 56-65 (2003).
14 Granoff, B. Kinetics of graphitization of carbon-felt-carbon matrix composites. Carbon 12, 405-416 (1974).
15 Bourrat, X., Trouvat, B., Limousin, G., Vignoles, G. & Doux, F. Pyrocarbon anisotropy as measured by electron diffraction and polarized light. J. Mater. Res. 15, 92-101 (2000).
16 Reznik, B., Gerthsen, D. & Huttinger, K. J. Micro- and nanostructure of the carbon matrix of infiltrated carbon fiber felts. Carbon 39, 215-229 (2001).
17 Shi, R., Li, H. J., Yang, Z. & Kang, M. K. Deposition mechanism of pyrolytic carbons at temperature between 800-1200 degrees C. Carbon 35, 1789-1792 (1997).
18 Reznik, B., Li, A., Schoch, G., Lichtenberg, S. & Deutschmann, O. Microscopy of Columnar Structures in Pyrolytic Carbon Coatings. Carbon 2009 (2009).
19 Grisdale, R. O. The formation of carbon black. Journal of Applied Physics 24, 1082-1091 (1953).
20 Hu, Z. J. & Huttinger, K. J. Mechanisms of carbon deposition—a kinetic approach. Carbon 40, 624-628 (2002).

1. A process for the production of pyrolytic carbon comprising the steps of:
(A) depositing pyrolytic carbon on a substrate; and
(B) controlling the structure of the deposited pyrolytic carbon through use of a Volmer-Weber island growth model.

2. The process according to claim 1, wherein the controlling of the structure of the deposited pyrolytic carbon comprises the manipulation of one or more of the following parameters:
a. the rate of nucleation;
b. the rate of growth;
c. the elevation of a portion of the substrate surface.

3. The process according to claim 2, wherein the controlling of the structure of the deposited pyrolytic carbon comprises the manipulation of two or more of said parameters.

4. The process according to claim 2, wherein the controlling of the structure of the deposited pyrolytic carbon includes the manipulation of all said parameters.

5. The process according to claim 2, wherein the controlling of the structure of the deposited pyrolytic carbon comprises the manipulation of the elevation of a portion of the substrate surface.

6. The process according to claim 5, wherein the portion of elevated substrate surface is in the range of 0.01% to 50% of the total surface of the substrate.

7. The process according to claim 5, wherein the elevated surface is a plurality of protrusions emanating from a base surface of the substrate.

8. The process according to claim 7, wherein the protrusions are arranged in a geometric pattern on the base surface of the substrate.

9. The process according to claim 6, wherein the elevated surface is configured to promote the preferential formation of nucleation sites relative to a base surface of the substrate.

10. The process according to claim 2, wherein the elevated portion is at least 100 nm and no more than 1 cm above a base surface of the substrate.

11. The process according to claim 1, wherein the Volmer-Weber 3D island growth model comprises the following constraints:
a. nucleation sites are randomly distributed on a flat surface at a constant rate per unit area;
b. once a nucleus is generated it grows at a constant radial growth velocity in free (non-occupied) directions; and
c. nucleation sites accumulate only on the substrate.

12. The process according to claim 1, wherein the Volmer-Weber 3D island growth model comprises the following constraints:
a. nucleation sites are preferentially distributed on the elevated substrate at a constant rate per unit area;
b. once a nucleus is generated it grows at a constant radial growth velocity in free (non-occupied) directions; and
c. nucleation sites accumulate only on the substrate.

13. A substrate for receiving a pyrolytic carbon coating as defined in claim 6.

14. A pyrolytic carbon coated substrate comprising the substrate of claim 13 and wherein the ratio of the height of the elevated portion of the substrate to the base surface of the substrate to the height of the pyrolytic carbon coating to the base surface of the substrate is at least 0.05 and no more than 0.5.

15. A medical implant comprising the pyrolytic carbon coated substrate of claim 14.

16. A process for the manufacture of a pyrolytic carbon coated substrate comprising coating a substrate according to the process of claim 6.

17. The process according to claim 4, wherein the controlling of the structure of the deposited pyrolytic carbon comprises the manipulation of the elevation of a portion of the substrate surface.

18. The process according to claim 17, wherein the portion of elevated substrate surface is in the range of 0.01% to 50% of the total surface of the substrate.

19. The process according to claim 18, wherein the elevated surface is a plurality of protrusions emanating from a base surface of the substrate.

20. The process according to claim 19, wherein the elevated portion is at least 100 nm and no more than 1 cm above a base surface of the substrate.
